(19) United States
(12) Patent Application Publication
(10) Pub. No.: US 2002/0117753 A1
(43) Pub. Date: Aug. 29, 2002

(54) Three dimensional packaging

(76) Inventors: Michael G. Lee, San Jose, CA (US); Wen-chou Vincent Wang, Cupertino, CA (US)

Correspondence Address: COUDERT BROTHERS, 600 Beach Street, San Francisco, CA, 94109, US

(21) Appl. No.: 09/792,479

(22) Filed: Feb. 23, 2001

(51) Int. Cl. H01L 23/48; H01L 23/52; H01L 29/40

(52) U.S. Cl. 257/758

(57) ABSTRACT

A method for forming a multilayer circuit substrate is disclosed. Preferably, a multilayer circuit substrate precursor is formed using a build up process. The multilayer circuit substrate precursor comprises an internal conductive post, an internal conductive layer coupled to one end of the conductive post, and an dielectric layer disposed around the conductive post. The multilayer circuit substrate precursor and the conductive post are cut to form a side electrical contact structure from the cut post.

### BACKGROUND OF THE INVENTION

1. Field of the Invention

Embodiments of the present invention relate to multilayer circuit substrates. More specifically, embodiments of the present invention provide for multilayer circuit substrates and methods for producing the same.

2. Description of the Prior Art

Many systems use “multichip modules,” i.e., packages housing IC chips. Typical multichip modules include a circuit substrate with chips disposed on the circuit substrate. The first multichip modules were two-dimensional. That is, all of the IC chips housed in the package were mounted on a single circuit substrate. Subsequently, three-dimensional multichip modules were developed to increase the density of IC chips that could be housed in a single package.

In three-dimensional multichip modules, multiple circuit substrates with chips are stacked on top of each other. In the modules, signal, power and ground lines are routed not only within the plane of the respective substrates, but also from one substrate to the next. For example, if the plane in which a substrate lies is defined to be the x-y plane, in order to communicate with IC chips mounted on different substrates within the stack, signals must also be routed in the z direction through a number of z-connections disposed between adjacent substrates.

While three-dimensional multichip modules of this type are effective in some instances, the use of only stacked substrates in a multichip module limits the potential design, device density, geometry, and signal routing capabilities of the multichip module. For example, the ability of chips on different substrates to communicate with each other is limited by the number and spacing of the z-connections between adjacent circuit substrates. Because the chips occupy space on the circuit substrates, the number of z-connections is limited to the space on the planar surfaces of the circuit substrates not occupied by the chips. Also, the input and output terminal locations on conventional circuit substrates is limited to the planar surfaces of the circuit substrates. The limited number of input and output terminals can limit the number of signals passing to and from the chips on the circuit substrates, thus limiting the performance of the multichip module. Thus, what is needed and what has been invented is an improved multilayer circuit substrate, and method for producing the same, without the deficiencies associated with conventional multilayer circuit substrates.

### SUMMARY OF THE INVENTION

Embodiments of the invention are directed to circuit substrates having a side electrical contact structure. The circuit substrates can have a large number of input and output terminals, so that more signals can pass into and out of the circuit substrates and to the chips disposed on the circuit substrates. Moreover, groups of circuit substrates can be joined together in any suitable manner. The arrangement of circuit substrates in a multichip module is not limited to stacking. In embodiments of the invention, a multichip module with a greater device density, smaller size, and enhanced operational performance can be designed.

One embodiment of the invention provides a method. The method comprises: forming a multilayer circuit substrate precursor using a build up process, wherein the multilayer circuit substrate precursor comprises an internal conductive post (which may be formed by electroplating), an internal conductive layer coupled to one end of the conductive post, and a dielectric layer (e.g., a polymeric dielectric layer) disposed around the conductive post; and cutting the multilayer circuit substrate precursor and the conductive post to form a side electrical contact structure from the cut post. Cutting preferably comprises the multilayer circuit substrate precursor with a laser. The internal conductive layer may be a first internal conductive layer, and the multilayer substrate precursor may preferably comprise a second internal conductive layer. The first and second internal conductive layers may be coupled to opposite ends of the conductive post. Forming the multilayer circuit substrate precursor preferably includes forming the condutive post, depositing a dielectric material on the conductive post, and polishing the deposited dielectric material to form the dielectric layer and expose an end of the conductive post. The conductive post may be formed by electroplating.

A further method for embodiments of the present invention includes forming the multilayer circuit substrate with a side electrical contact structure; placing a conductive body on the side electrical contact structure; and electrically coupling another multilayer circuit substrate to the first multilayer circuit substrate via the conductive body. A fill material may be deposited between the two multilayer circuit substrates and around the conductive body. Preferably, the two multilayer circuit substrates are disposed perpendicular to each other after coupling. Preferably further, the multilayer circuit structure precursor comprises a stack of conductive posts having a first end and a second end, and wherein cutting comprises cutting the multilayer circuit substrate through the stack conductive posts from the first end to the second end of the stack of conductive posts.

Another embodiment of the invention provides an electrical assembly. The electrical assembly comprises: a conductive body; a first multilayer circuit substrate having opposing sides, and a side electrical contact structure disposed between the opposing sides of the first multilayer circuit structure; and a second multilayer circuit substrate, wherein the conductive body is disposed on the side electrical contact structure and the first and second circuit substrates are coupled to each other via the conductive body. The electrical assembly further comprises a fill material disposed around the conductive body which includes a thin film flexible interconnector.

Another embodiment of the invention provides a multilayer circuit substrate. The circuit substrate comprises: a first planar surface and a second planar surface wherein the first and second planar surfaces are opposite to each other; a side electrical contact structure disposed between the first and second surfaces; a conductive layer between the first and second surfaces wherein the conductive layer is electrically coupled to the side electrical contact structure and is internal to the multilayer circuit substrate; and a dielectric layer (e.g., a polymeric dielectric layer). The side electrical contact structure includes a cut conductive post.

These provisions together with the various ancillary provisions and features which will become apparent to those skilled in the art as the following description proceeds, are attained by the methods and multilayer circuit substrate of the present invention, preferred embodiments thereof being shown with reference to the accompanying drawings, by way of example only, wherein:

### BRIEF DESCRIPTION OF THE DRAWINGS

FIGS. 1 to 9 show cross-sections of circuit substrate precursors used to illustrate a method for forming a circuit substrate.

FIGS. 10 to 12 show cross-sections of circuit substrates which are used to illustrate a method for joining circuit substrates.

FIG. 13 shows a cross section coupled circuit substrates in side-by-side relationship and a perpendicular relationship.

FIG. 14 shows a cross-section of a circuit substrate with a side electrical contact structure and a wire bond structure coupled to the side electrical contact structure.

FIG. 15 shows a cross-section of an assembly with a circuit substrate with a side electrical contact structure and a thin film interconnector coupled to the side electrical contact structure.

It is to be understood that for clarity of illustration, some drawings may not be to scale.

### DETAILED DESCRIPTION OF PREFERRED EMBODIMENTS OF THE INVENTION

In embodiments of the invention, side electrical contact structures on a circuit substrate can be made quickly and easily. For instance, in preferred embodiments, a circuit substrate precursor can be formed using a build up process. In a typical build up process, conductive layers and dielectric layers are sequentially formed to form a circuit substrate precursor. After the circuit substrate precursor is formed, the circuit substrate precursor is cut, e.g., with a laser at a region where an internal conductive post is present. In preferred embodiments, the internal conductive post is in a stack, and the stack is cut. Preferably, the conductive post is cut from one end to the other. If a stack of posts is cut, cutting preferably occurs from one end of the stack to the other. The cut conductive post or posts form a side electrical contact structure.

Forming a circuit substrate with a side electrical contact structure in this manner is advantageous. For example, because the side electrical contact structure is formed by cutting, additional side metallization steps are not needed to provide an electrically conductive region on the side of the circuit substrate. Consequently, the number of steps needed to form a circuit substrate having a side electrical contact structure are reduced. Moreover, since the circuit substrate precursor is formed using a build up process, posts can be formed so that they will be at pre-selected locations within the formed circuit substrate. Also, conductive posts of any desired size or shape can be formed, and conductive posts can be stacked to increase the size of the formed side electrical contact structure. Consequently, side electrical contact structures of any desired size may be formed at any suitable location in the circuit substrate. For example, using the build up process, posts can be formed on top of each other to form a stack of posts of a desired height within the circuit substrate precursor. The circuit substrate precursor and the stack are then cut. If the post is cylindrical, the side electrical contact structure may have an external surface having an area corresponding to the area of the height times the diameter of the posts.

The formed circuit substrates can be coupled to other circuit substrates or other devices which may have a different configuration or shape. When the circuit substrates are coupled together, they can be oriented in any suitable manner in relation to each other. For example, the circuit substrates may be oriented perpendicular to each other. In embodiments of the invention, the design of a multichip module is not limited as may be the case in a multichip module with only stacked substrates. Moreover, the circuit substrates according to embodiments of the invention may have terminals at the side surfaces and at the opposing planar surfaces of the circuit substrate. Increased access is provided to the chips on the circuit substrate, thus enhancing the overall performance capability of the formed multichip module.

Also, in preferred embodiments, complicated coupling devices (e.g., male/female connectors) which might otherwise take up space in a module, are not needed. For example, in some preferred embodiments, circuit substrates can be coupled together using a conductive material and a fill material. In yet other embodiments, conductive bodies such as thin film connectors and wire bond devices may be used.

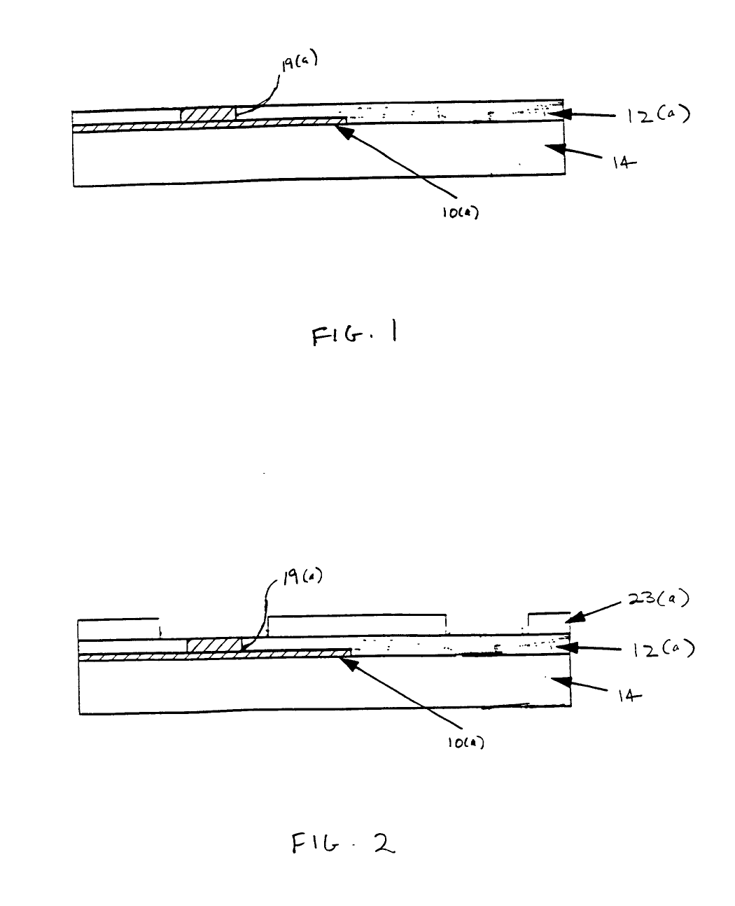

An embodiment for forming a circuit substrate with a side electrical contact structure can be described with reference to FIGS. 1 to 9.

FIG. 1 shows a support substrate 14 which is capable of supporting a plurality of dielectric and conductive layers when forming a circuit substrate precursor. The support substrate 14 may be temporary or permanent. The support substrate 14 may comprise a material such as glass, or an etchable material such as aluminum. If the support substrate 14 is permanent, it may be cut along with the precursor, and may remain attached to the circuit substrate after it is formed. The support substrate 14 may optionally include circuitry. For example, the support substrate 14 may be a rigid substrate with circuitry or a ceramic substrate with pins. As shown in FIG. 1, a conductive layer 10(a) and a dielectric layer 12(a) are disposed on the support substrate 14. A conductive post 19(a) is disposed on the conductive layer 10(a) and is also disposed within an aperture in the dielectric layer 12(a).

As shown in FIG. 2, a patterned photoresist layer 23(a) is formed on the dielectric layer 12(a). The patterned photoresist layer 23(a) may include a negative or positive photoresist material, and can be formed using photolithography. In a typical photolithography process, a photoresist layer is deposited on the dielectric layer 12(a). The deposited photoresist layer is then irradiated with a pattern of radiation. Then, the irradiated or non-irradiated portions of the photoresist layer may be removed, depending upon whether the photoresist material is positive or negative, to form a patterned photoresist layer 23(a). The pattern formed by the patterned photoresist layer 23(a) may correspond the pattern of the conductive layer to be formed. For instance, the patterned photoresist layer be the negative image of the patterned conductive layer to be formed.

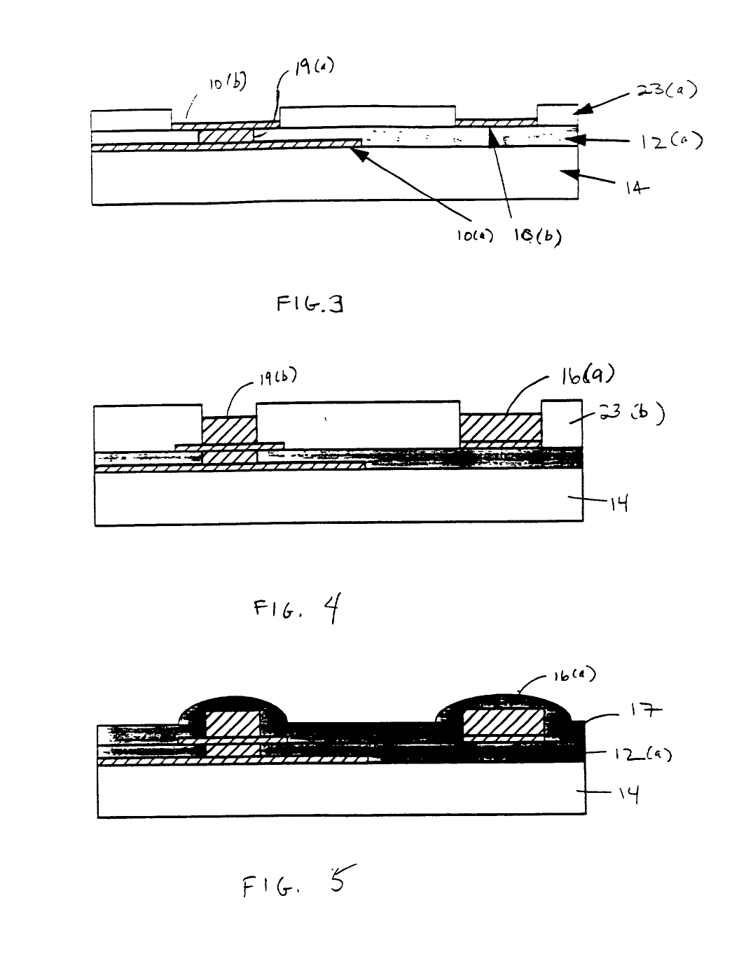

Referring now to FIG. 3, after the patterned photoresist layer 23(a) is formed, a patterned conductive layer 10(b) may be formed in the areas not occupied by the patterned photoresist layer 23(a). The conductive layer 10(b) can have any suitable thickness including a thickness of about 0.01 microns or less, and preferably between about 0.001 microns and about 0.01 microns. Preferred linewidths in the conductive layer 10(b) are in the range between about 0.10 micron and about 0.30 micron. The patterned photoresist layer 23(a) can be used as a mask to form the patterned conductive layer 10(b).

In embodiments of the invention, additive processes such as electrolytic plating, electroless plating, and sputtering are preferably used to form the conductive layer 10(b). If plating is used to form the conductive layer 10(a), a thin seed layer (not shown) can be deposited on the dielectric layer 12(a) prior to forming the patterned photoresist layer 23(a). The seed layer can help to initiate the plating process. After the conductive layer 10(b) is formed within the patterned photoresist layer 23(a), the photoresist layer 23(a) is stripped. If a seed layer is present, the seed layer can be flash etched after the photoresist layer 23(a) is stripped.

Although FIGS. 1 to 3 illustrate the formation of a conductive layer 10(b) using an additive process, the conductive pattern 10(b) can be formed using a subtractive process. In an exemplary subtractive process, a continuous layer of metal can be deposited on the dielectric layer. A patterned photoresist layer is then formed on the continuous layer of metal, and an etchant is used to etch the continuous layer of metal at regions not covered by the patterned photoresist layer to form a patterned conductive layer. After the patterned conductive layer is formed, the patterned photoresist layer 23 is stripped leaving the patterned conductive layer.

With reference to FIG. 4, after the patterned conductive layer 10(b) is formed, conductive posts 16(a), 19(b) can be formed on the patterned conductive layer 10(b). More specifically, a patterned photoresist layer 23(b) with apertures is formed on the first conductive layer 10(a), and the conductive posts 16(a), 19(b) are formed within the apertures. The conductive posts 16(a), 19(b) may be formed using the same or different process as used to form the previously described conductive layers. For example, electrolytic plating, electroless plating, or sputtering can be used to form the conductive posts 16(a). If plating is used to form the conductive posts 16(a), a seed layer (not shown) may be deposited on the conductive pattern 10(b) and the dielectric layer 12(a) prior to forming the patterned photoresist layer 23(a). The seed layer can help initiate the plating of the conductive posts. In some embodiments, a seed layer is not needed. For example, the portions of the patterned conductive layer 10(b) exposed through the patterned photoresist layer 23(b) can initiate the plating process.

As shown in FIG. 4, one end of each conductive post 16(a), 19(b) is disposed proximate to the patterned conductive layer 10(b), while the other end is free and is disposed distal to the patterned conductive layer 10(b). The conductive posts 16(a), 19(b) may have any suitable aspect ratio. Preferably, the conductive posts are cylindrical in shape and may have an aspect ratio greater than about 1.0 microns. A typical post may have a height of about 1.0 microns or less and a diameter of about 0.10 microns or less.

The patterned conductive layer 10(b) and the conductive posts 16(a), 19(b) may comprise any suitable conductive material. Examples of suitable conductive materials include copper, nickel, and gold, or the like.

After the conductive posts 16(a), 19(b) are formed, the patterned photoresist layer 23(b) is stripped leaving a plurality of freestanding conductive posts disposed on the patterned conductive layer 10(b). If a seed layer was used in the formation of the conductive posts 16(a), 19(b), the seed layer may be flash etched after the patterned photoresist layer 23(b) is stripped.

After the conductive posts 16(a), 19(b) are formed, a dielectric layer is formed around the conductive posts 16(a), 19(b). The dielectric layer 23(b) may include any suitable material. Exemplary dielectric materials include polymeric materials such as polyimides, or the like. The dielectric layer 23(b) may have any suitable thickness. Preferably, the thickness of the dielectric layer 23(b) is less than about 50 microns, more preferably between about 10 microns and about 50 microns.

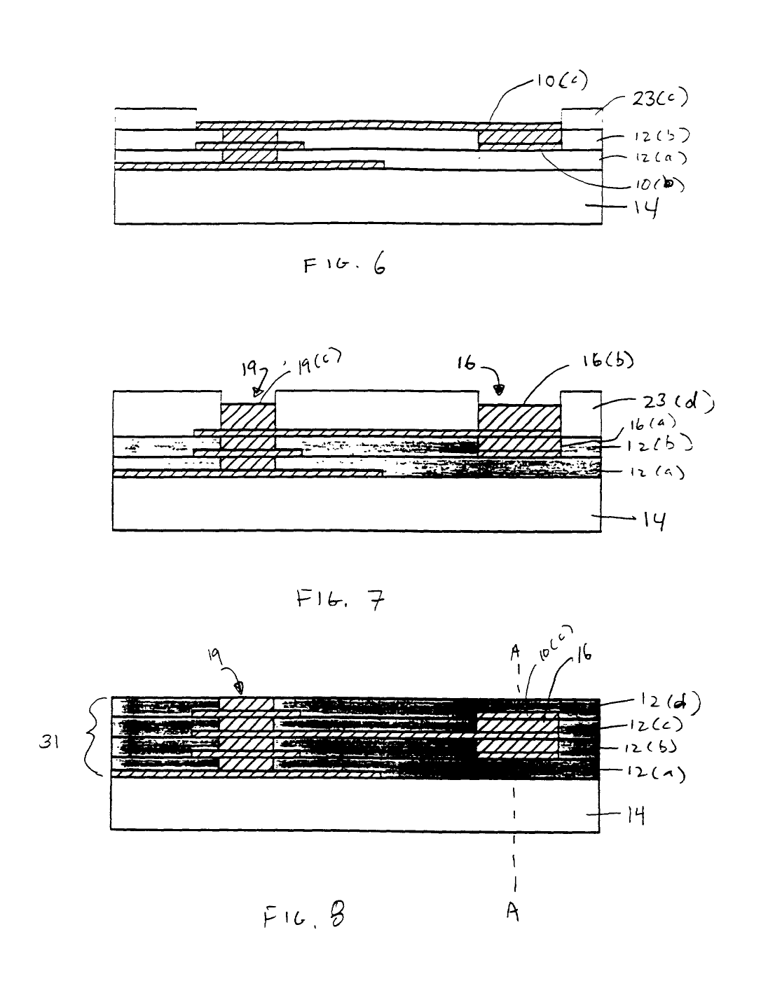

With reference to FIG. 5, a dielectric material 17 is deposited on the substrate 14 and over the conductive posts 16(a), 19(b). The dielectric material 17 may be deposited using any suitable process including spin coating, curtain coating, or roller coating. The dielectric material 17 may alternatively be in the form of a pre-formed sheet which is laminated to the substrate 14 and over the conductive posts 16(a), 19(b). After the dielectric material 17 is deposited on the support substrate 14, it may be cured.

After the dielectric material 17 is deposited, some of the dielectric material 17 may be disposed on the ends of the posts 16(a), 19(b) and some of the dielectric material 17 may be disposed between the posts 16(a), 19(b). The upper surface of the deposited dielectric material 17 may be uneven as a result of the unevenness of the underlying surface. After the dielectric material 17 is deposited on the conductive posts 16(a), 19(b) it may be polished using a process such as a chemical mechanical polishing (CMP) process. Polishing removes dielectric material which is disposed on the ends of the conductive posts, and exposes the ends of the conductive posts. Polishing also planarizes the dielectric material. After polishing, a planar dielectric layer 12(b) is formed. In other embodiments, polishing is not needed. For example, if a pre-formed dielectric layer is laminated to the dielectric layer 12(a), the laminated layer may be already substantially planar so that polishing may not be necessary.

With reference to FIG. 6, after the conductive posts 16(a), 19(b) are formed, another patterned conductive layer 10(c) is formed on the previously formed dielectric layer 12(b). Ends of the conductive posts 16(a), 19(b) can be coupled together with the patterned conductive layer 10(c). The conductive posts 16(a) and 19(b) are thus sandwiched between the subsequently and previously formed conductive layers 10(b) and 10(c).

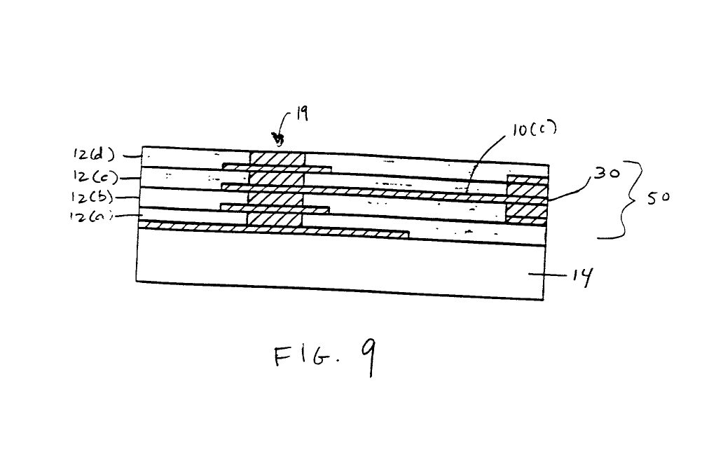

If the side electrical contact structure to be formed is to have a large area, external conductive surface, multiple conductive posts can be stacked and then cut to form a side electrical contact structure. Any suitable number of conductive posts can be stacked on each other depending upon the desired size of the side electrical contact structure to be formed. For example, a stack of conductive posts may comprise two or more, or three or more stacked posts. With reference to FIG. 7, an apertured photoresist layer 23(d) may be formed on the dielectric layer 12(b), and conductive posts 16(b), 19(c) may be formed in the apertures in the apertured photoresist layer 25(b). The conductive posts 16(b), 19(c) may be formed in the same or different manner as the previously formed conductive posts 16(a), 19(b).

As shown in FIG. 8, after the desired number of conductive posts are formed, additional posts, conductive layers 10(c) and dielectric layers 12(c), 12(d) can be formed in the same or different manner as the previously described conductive posts, conductive layers, or dielectric layers to form a circuit substrate precursor 31. The circuit substrate precursor 31 may be flexible or rigid, depending upon the desired properties of the formed circuit substrate. The circuit substrate precursor 31 includes a stack of conductive posts 16 (or a single conductive post) at an internal region of the circuit substrate precursor 31. This stack of conductive posts 16 is preferably electrically coupled internally to other electrical structures such as other post stacks 19 via at least one conductive layer 10(c).

Once the precursor 31 is formed, the stacked post structure 16 in the circuit substrate precursor 31 is then cut, for example along the line A--A in FIG. 8 to form a side electrical contact structure. Two circuit substrates with side electrical contact structures may be formed. The stacked post structure 16 can be cut using any suitable process. For example, the stacked post structure can be cut with a laser or a dicing saw. The conductive layers 10(a), 10(b), 10(c) and conductive posts 16(a), 16(b) will form the side electrical contact structure when they are cut. The dielectric layers 12(a)-12(d) as well as the support substrate 14 can also be cut along with the stacked post structure. The cut support substrate 14 can be removed from the formed circuit substrate or may remain with the formed circuit substrate. In some embodiments, the support substrate 14 may be removed from the circuit substrate precursor 31 prior to cutting. For example, the circuit substrate precursor 31 may be peeled off of the support substrate 14, or the support substrate 14 may be decomposed by, e.g., etching prior to cutting the precursor 31.

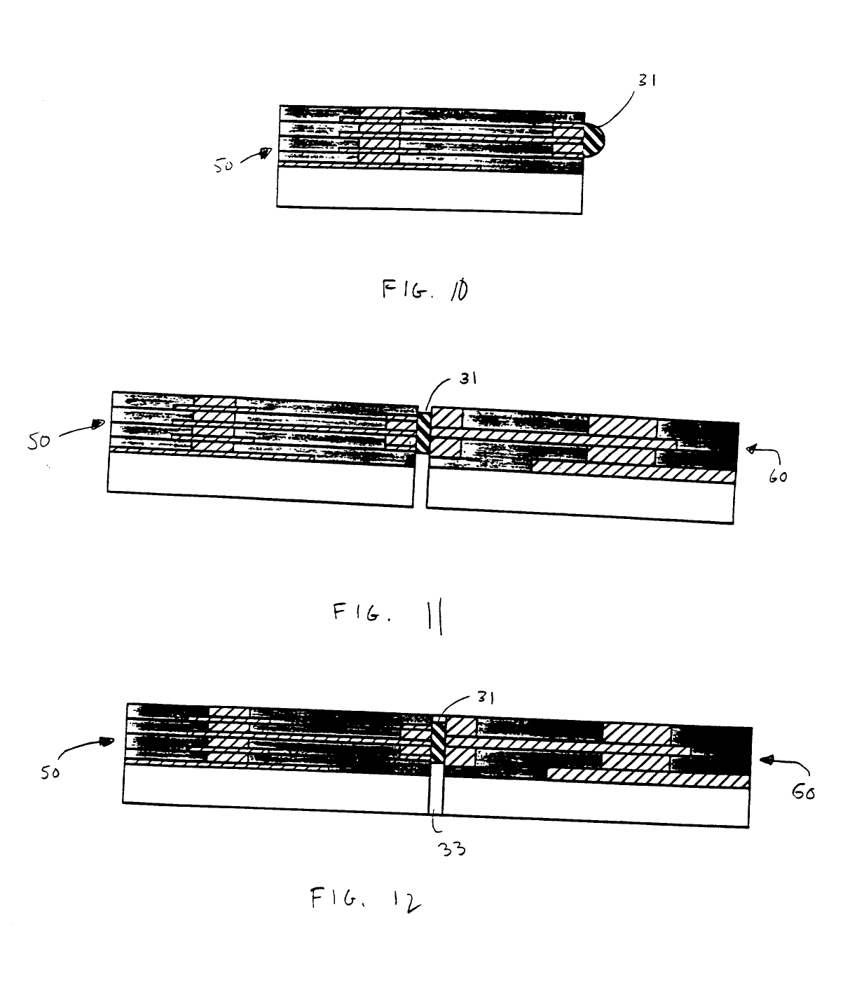

As shown in FIG. 9, after cutting, a circuit substrate 50 having a side electrical contact structure 30 is formed. The circuit substrate 50 has a side electrical contact structure 30 where the internal stacked post substrate is cut. The side electrical contact structure 30 has an external surface which forms a portion of the side surface of the circuit substrate. A portion of the side electrical circuit structure 30 is disposed inwardly from the side surface of the circuit substrate. The side electrical contact structure 50 may include a portion of the conductive layer 10(c) disposed between opposite ends of the side electric contact structure 30. As noted above, the conductive posts which are cut are preferably cylindrically shaped. Accordingly, after cutting, the formed side electrical contact structure may include a number of cylinder-shaped portions (e.g., stacked semi-cylinders). The circuit substrate 50 may have one or more conductive patterns which are coupled to the cut post structure. One or more chips (not shown) may be mounted on top surface of the circuit substrate 50 in the formation of a multichip module. Mounting may occur using any suitable process including a flip-chip bonding process.

The embodiments described with reference to FIGS. 1 to 9 are for illustration purposes and are not intended to be limiting. For example, although FIGS. 1 to 6 show the formation of the conductive posts 16(a), 19(b) prior to forming the dielectric layer 12(b), this sequence of steps need not be used in other embodiments. For example, an apertured dielectric layer may be formed by, for example, depositing a dielectric material on a substrate. Apertures may be formed in the deposited dielectric material. For example, if the dielectric material is photoimageable, then apertures may be formed by pattern irradiation and developing. In another example, apertures may be formed in a dielectric material using a laser. Conductive posts can then be formed within the apertures using sputtering, plating, or any other suitable method.

After the desired circuit substrate 50 is formed, the side electrical contact structure 30 of the circuit substrate 50 can be used to electrically couple the circuit substrate 50 to any other circuit substrate, device or apparatus to form an electrical assembly. The other structure may have different wiring patterns and/or different feature densities.

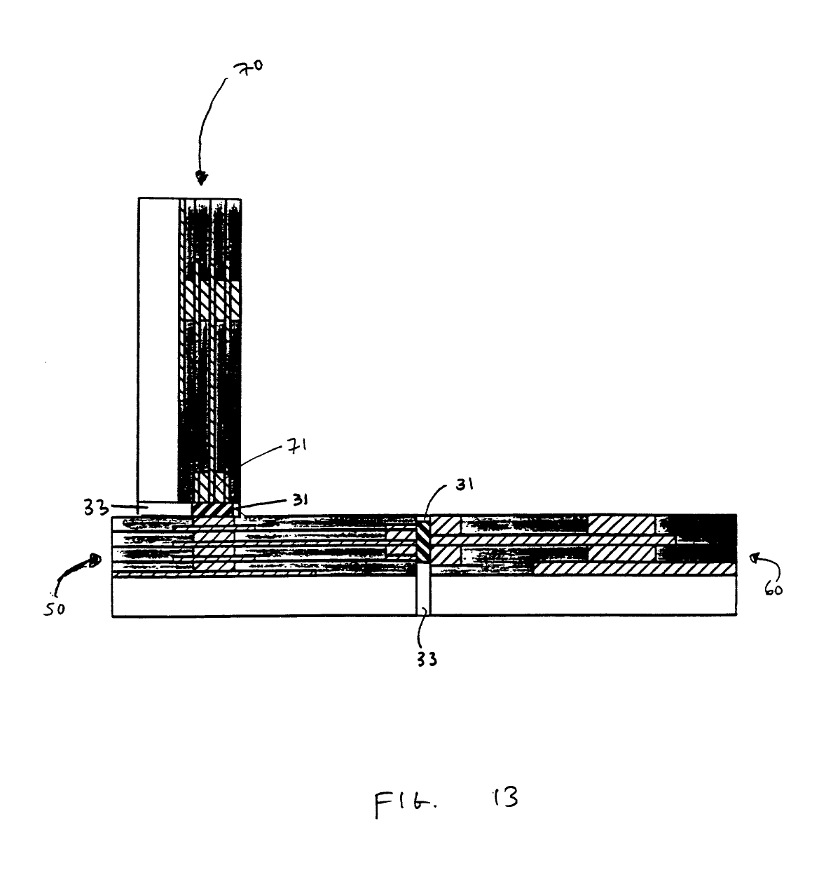

In some embodiments, circuit substrates can be joined together in a side-by-side relationship. For example, as shown in FIG. 10, a conductive body 31 may be placed on the side electrical contact structure 30 of a circuit substrate 50. Any suitable process including electroless deposition or paste printing can be used to deposit the conductive body 31 on the side electrical contact structure 30. The conductive body 31 may be, for example, solder or a conductive adhesive. The conductive body 31 can then contact a side electrical contact structure on a second circuit substrate 60, which may have been formed in the same or different manner as the first circuit substrate 50. As shown in FIGS. 11 and 12, after the first and second circuit substrates 50, 60 are joined together, a fill material 33 may be deposited between the first and second circuit substrates 50, 60 and around the conductive material 31. The fill material is then optionally cured to form a reliable mechanical and electrical connection between the first and second circuit substrates 50, 60. Preferably, the fill material comprises a polymeric material including epoxy-based materials, polyimides, or any other suitable polymer.

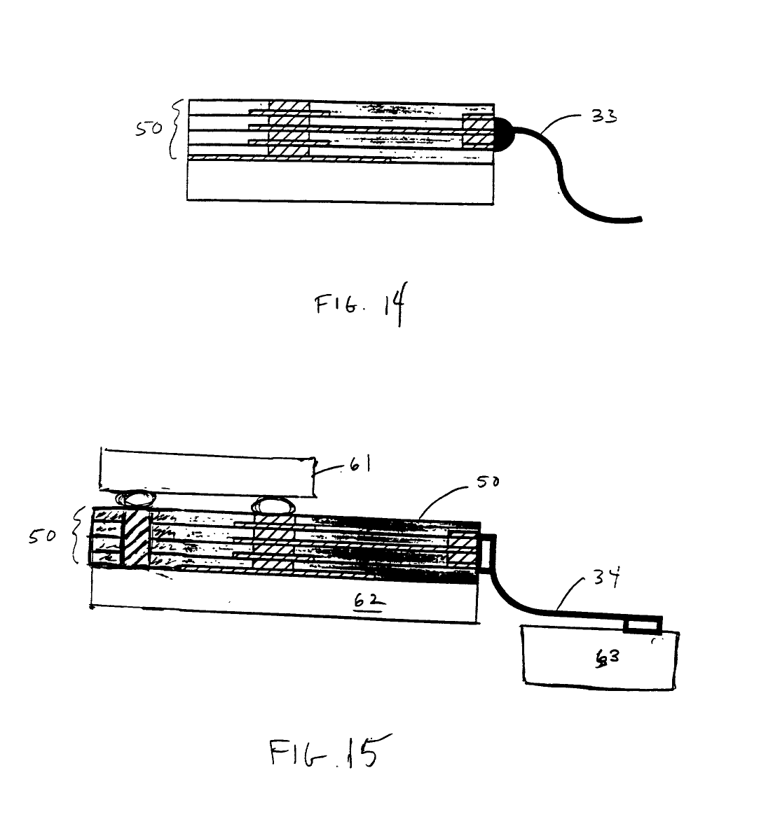

In other embodiments, coupled circuit substrates may be disposed perpendicular to each other. For example, with reference to FIG. 13, a third circuit substrate 70 may be coupled to the first circuit substrate 50, which is coupled to the second circuit substrate 60. Each of the circuit substrates 50, 60, 70 may be joined together with a conductive body 31 and a fill material 33 disposed around the conductive body 31. The third circuit substrate 70 is perpendicular to the first circuit substrate 50 and is electrically coupled thereto via the side electrical contact structure 71 of the third circuit substrate 70. If desired, the first circuit substrate 70 may serve as a high-density z-connect to other stacked substrates.

Other conductive bodies may be coupled to the side electrical contact structure of the circuit substrate. Examples include thin film interconnectors and wire bonding structures. As shown in FIG. 14, a wire bonding structure 33 is coupled to a side electrical contact structure of the multilayer circuit substrate 50. In FIG. 15, a flexible thin film interconnector 34 is coupled to a side electrical contact structure on the multilayer circuit substrate 50. Suitable thin film interconnectors are described in U.S. Pat. No. 5,419,038, which is assigned to the same assignee as the present application and which is hereby incorporated by reference in its entirety for all purposes. Structures such as the wire bonding structure 33 and the flexible thin film interconnector 34 may be joined to other electrical structures such as a chip or a circuit board. A connection can be made to signal, power, or ground.

The presence of the side electrical contact structure permits a greater number of potential signal routing paths to the circuit substrate and consequently to any chips on the circuit substrate. Conductive pathways within the circuit substrate may be accessed through either planar face of the circuit substrate or at the side regions of the circuit substrate. For example, as shown in FIG. 15, the circuit substrate 50 can communicate with a chip 61 disposed on one planar surface of the circuit substrate 50, while the other planar surface of the circuit substrate is in communication with a circuitized support substrate 62 (the circuitry is not shown). The flexible thin film interconnector 34 can couple the circuit substrate 50 to another electrical device 63 via a side electrical contact structure. The number of potential input and output terminals on the external surfaces on the circuit substrate 50 are increased, thus increasing the access to any chips disposed on the circuit substrate 50. In embodiments of the invention, input and output terminals can be present at any exterior surface of the circuit substrate 50 including the side surfaces.

Also, in embodiments of the invention, an electronic package such as a three dimensional multichip module or a single-chip module can be formed quickly and efficiently. The circuit substrates in a multichip module can be disposed at any desired relation to each other using the side electrical contact structures present on the substrates. Consequently, the number of potential multichip module design configurations is increased over conventional multichip modules with only stacked circuit substrates. Circuit substrates within a module can be connected more efficiently so that the space occupied by the module can be reduced.

Also, signal routing distances between chips on different circuit substrates can be reduced, thus resulting in a smaller and faster electronic packages. For instance, in a multichip module embodiment with chips on perpendicular circuit substrates, signals can pass from a chip on a vertical circuit substrate to a chip on a horizontal circuit substrate by passing in a y-direction through the vertical circuit substrate and then in an x-direction through the horizontal circuit substrate. If the chips are on circuit substrates which are parallel and stacked, signals can pass in an x-direction from a chip though a first stacked substrate to a z-connection, through the z-connection, and again in an x-direction through a second stacked substrate from the z-connection to a chip on the second stacked substrate. In embodiments of the invention, more direct signal paths between chips on different substrates are present, so that signal routing distances between chips on different circuit substrates are reduced, thus resulting in enhanced package performance.

The terms and expressions which have been employed herein are used as terms of description and not of limitation, and there is no intention in the use of such terms and expressions of excluding equivalents of the features shown and described, or portions thereof, it being recognized that various modifications are possible within the scope of the invention claimed. Moreover, any one or more features of any embodiment of the invention may be combined with any one or more other features of any other embodiment of the invention, without departing from the scope of the invention. Thus, while the present invention has been described herein with reference to particular embodiments thereof, a latitude of modification, various changes and substitutions are intended in the foregoing disclosure, and it will be appreciated that in some instances some features of the invention will be employed without a corresponding use of other features without departing from the scope and spirit of the invention as set forth. Therefore, many modifications may be made to adapt a particular situation or material to the teachings of the invention without departing from the essential scope and spirit of the present invention. It is intended that the invention not be limited to the particular embodiment disclosed as the best mode contemplated for carrying out this invention, but that the invention will include all embodiments and equivalents falling within the scope of the appended claims.

What is claimed is:

1. A method comprising:
forming a multilayer circuit substrate precursor using a build up process, wherein the multilayer circuit substrate precursor comprises an internal conductive post, an internal conductive layer coupled to one end of the conductive post, and an dielectric layer disposed around the conductive post; and
cutting the multilayer circuit substrate precursor and the conductive post to form a side electrical contact structure from the cut post.

2. The method of claim 1 wherein cutting comprising cutting the multilayer circuit substrate precursor with a laser.

3. The method of claim 1 wherein the internal conductive layer is a first internal conductive layer and wherein the multilayer substrate precursor comprises a second internal conductive layer, wherein the first and second internal conductive layers are coupled to opposite ends of the conductive post.

4. The method of claim 1 wherein the dielectric layer comprises a polymeric material.

5. The method of claim 1 wherein forming the multilayer circuit substrate precursor comprises
forming the conductive post;
depositing a dielectric material on the conductive post; and
polishing the deposited dielectric material to form the dielectric layer and expose an end of the conductive post.

6. The method of claim 1 wherein the conductive post is formed by electroplating.

7. A method comprising:
forming a first multilayer circuit substrate with a side electrical contact structure according to the method of claim 1,
placing a conductive body on the side electrical contact structure; and
electrically coupling a second multilayer circuit substrate to the first multilayer circuit substrate via the conductive body.

8. The method of claim 7 further comprising:
depositing a fill material between the first and second multilayer circuit substrates and around the conductive body.

9. The method of claim 7 wherein the first and second multilayer circuit substrates are disposed perpendicular to each other after coupling.

10. The method of claim 1 wherein the dielectric layer has a thickness of about 50 microns or less.

11. The method of claim 1 wherein the conductive post comprises copper.

12. The method of claim 1 wherein the multilayer circuit structure precursor comprises a stack of conductive posts having a first end and a second end, and wherein cutting comprises cutting the multilayer circuit substrate through the stack conductive posts from the first end to the second end of the stack of conductive posts.

13. A multilayer circuit substrate made according to the method of claim 1.

14. An electrical assembly comprising:
a conductive body;
a first multilayer circuit substrate having opposing sides, and a side electrical contact structure disposed between the opposing sides of the first multilayer circuit structure; and
a second multilayer circuit substrate, wherein the conductive body is disposed on the side electrical contact structure and the first and second circuit substrates are coupled to each other via the conductive body.

15. The electrical assembly claim 14 further comprising a fill material disposed around the conductive body.

16. The electrical assembly of claim 14 wherein the conductive body comprises a thin film flexible interconnector.

17. A multilayer circuit substrate comprising:
a first planar surface and a second planar surface wherein the first and second planar surfaces are opposite to each other;
a side electrical contact structure disposed between the first and second surfaces;
a conductive layer between the first and second surfaces wherein the conductive layer is electrically coupled to the side electrical contact structure and is internal to the multilayer circuit substrate; and
a dielectric layer.

18. The multilayer circuit substrate of claim 17 wherein the side electrical contact structure comprises a cut conductive post.

19. The multilayer circuit substrate of claim 17 wherein the dielectric layer comprises a polymeric material.

20. A chip module comprising:
a chip; and
the multilayer circuit substrate of claim 17, wherein the chip is disposed on the multilayer circuit substrate.

21. A multilayer circuit substrate made according to the method of claim 7.
